(19) United States
(12) Patent Application Publication
(10) Pub. No.: US 2007/0273014 A1
(43) Pub. Date: Nov. 29, 2007

(54) SYSTEM IN PACKAGE MODULE

(75) Inventors: Yong Bum LEE, GYUNGGI-DO (KR); Nam Gyun YIM, GYUNGGI-DO (KR)

Correspondence Address: LOWE HAUPTMAN HAM & BERNER, LLP, 1700 DIAGONAL ROAD, SUITE 300, ALEXANDRIA, VA, 22314, US

(73) Assignee: SAMSUNG ELECTRO-MECHANICS CO., LTD., GYUNGGI-DO (KR)

(21) Appl. No.: 11/624,490

(22) Filed: Jan. 18, 2007

(30) Foreign Application Priority Data
May 25, 2006 (KR) 10-2006-0047035

(51) Int. Cl. H01L 23/02

(52) U.S. Cl. 257/686

(57) ABSTRACT

A System in Package (SIP) module. The module includes a printed circuit board with at least one cavity formed therein. The module also includes at least one first device mounted in the cavity and a circuit pattern formed on an undersurface of the cavity and electrically connected to the first device. The module further includes at least one second device mounted on a printed circuit board surface corresponding to the undersurface of the cavity.

### CLAIM OF PRIORITY

This application claims the benefit of Korean Patent Application No. 2006-47035 filed on May 25, 2006, in the Korean Intellectual Property Office, the disclosure of which is incorporated herein by reference.

### BACKGROUND OF THE INVENTION

1. Field of the Invention

The present invention relates to a System in Package (SIP) module and, more particularly, to an SIP module which has a device mounted in a cavity formed in a printed circuit board to miniaturize a product.

2. Description of the Related Art

With recent rapid advancement in electronic industry, electronic products are required to be more miniaturized, light-weight and multi-functional in accordance with the needs of the user. As an assembly technique for accommodating such needs, homogenous or heterogeneous Integrated Circuit (IC) chips are integrated in a single unit module. One such packaging technique in line with this trend is System in Package (SIP).

An SIP module refers to a technology in which different types of semiconductor chips are arranged or stacked in one package, operating as a single complete system. In the SIP module, individual devices having various functions are mounted in a single package to utilize a given space, enabling miniaturization. However, in response to a recent demand for electronic products such as portable and slimmer mobile apparatuses, the area and height of the module is inevitably limited. In order to manufacture a small-sized SIP module, the sizes of the devices mounted therein have to be smaller, which however considerably increases the manufacturing costs of the devices and module. Further, in order to realize desired functions, some devices cannot be manufactured smaller than certain sizes.

FIGS. 1 and 2 are sectional views illustrating SIP modules according to the prior art.

Referring to FIG. 1, the SIP module 10 includes surface mounting devices 15 mounted on a substrate 11 and a resin encapsulant 18 for encapsulating an upper surface of the substrate 11 and the surface mounting devices 15. Of the surface mounting devices 15, a bare chip 16 is connected to the circuit pattern of the substrate by wires, with a chip bonding pad 19 wire-bonded to a circuit pattern 20 formed on the substrate 11. The SIP module can be mounted on a set board by Land Grid Array (LGA) method with a pad 19 formed on a bottom surface of the substrate 11 or by Ball Grid Array (BGA) method with solder balls provided on the pad 19.

Referring to FIG. 2, an SIP module 20 includes surface mounting devices 15 mounted on the substrate 11 and an IC chip 16 mounted by flip chip bonding. That is, the IC chip 16 is electrically connected to a circuit pattern (not shown) formed on the substrate 11 by bumps 26. To protect the devices 15 mounted on the substrate 19, a shield case 27 is placed over the top of the substrate 11.

However, in the SIP modules 10 and 20 described above, the devices are mounted on one side only of the substrate, thus limiting miniaturization and slimming of the modules. Thus, conversely, the modules can be miniaturized by reducing the size of the surface mounting devices 15, but this increases the manufacturing costs as mentioned above and some devices need to maintain their sizes to keep desired functions.

### SUMMARY OF THE INVENTION

The present invention has been made to solve the foregoing problems of the prior art and therefore an aspect of the present invention is to provide a System in Package module with devices mounted in a cavity formed in a side of a printed circuit board and other devices mounted to the other side opposed to the cavity, thereby obtaining a miniaturized and slim product.

According to an aspect of the invention, the invention provides a System in Package module. The module includes: a printed circuit board with at least one cavity formed therein; at least one first device mounted in the cavity; a circuit pattern formed on an undersurface of the cavity and electrically connected to the first device; and at least one second device mounted to a printed circuit board surface corresponding to the undersurface of the cavity. The SIP module can be electrically connected to the circuit pattern by wire bonding or flip chip bonding. The SIP module can further include a resin encapsulant for encapsulating the first device.

Preferably, a plurality of first devices can be mounted in one cavity.

The plurality of first devices can be mounted on the undersurface of the cavity in a stacked structure.

According to an embodiment of the present invention, the SIP module can further include a resin encapsulant for encapsulating the second device.

According to another embodiment of the present invention, the SIP module can further include a shield case for covering the second device.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 and 2 are sectional views illustrating conventional SIP modules;

FIG. 3 is a sectional view illustrating a SIP module according to an embodiment of the present invention; and

FIGS. 4 to 6 are sectional views illustrating SIP modules according to various embodiments of the present invention.

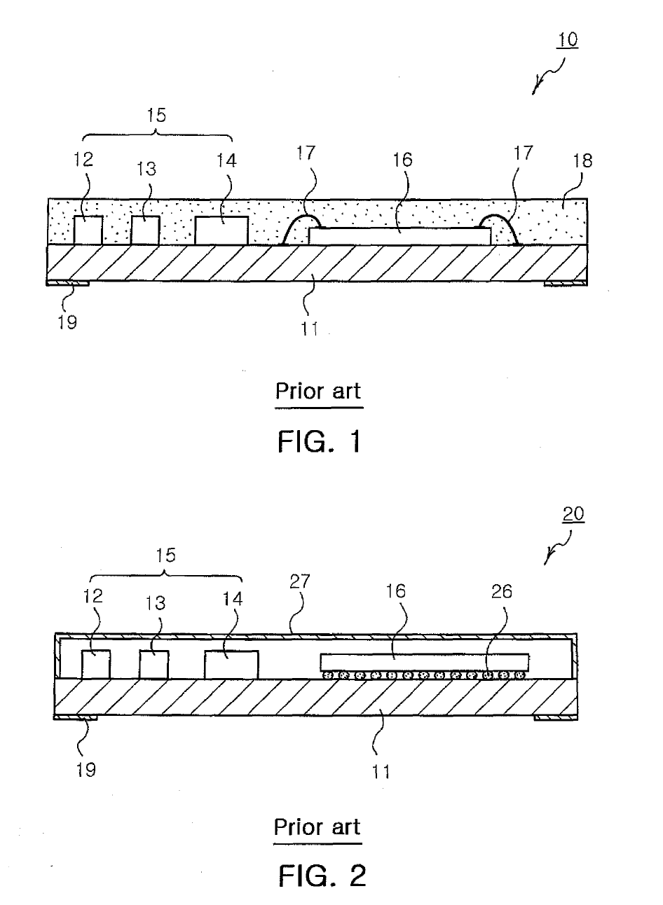

### DETAILED DESCRIPTION OF THE PREFERRED EMBODIMENT

Preferred embodiments of the present invention will now be described in detail with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference numerals are used throughout to designate the same or similar components.

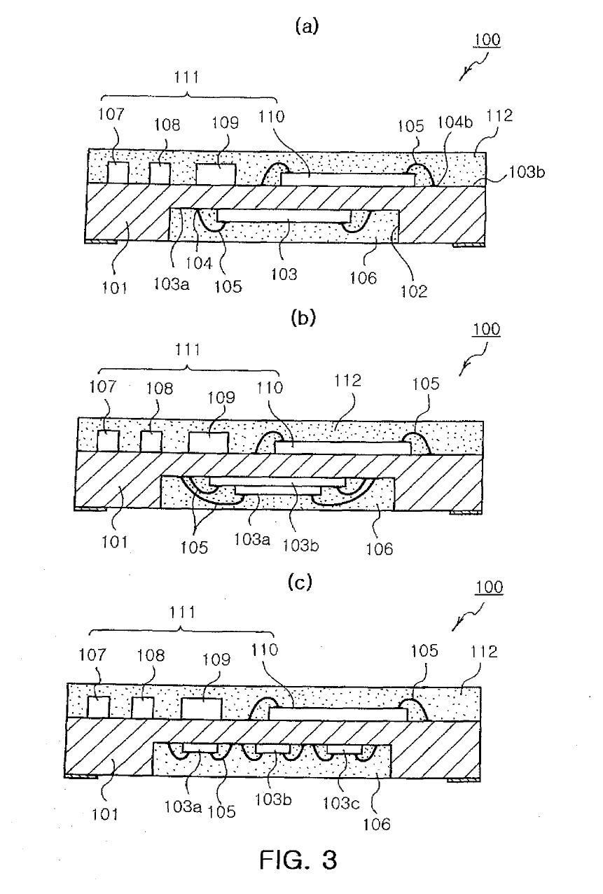

FIG. 3 presents sectional views illustrating SIP modules according to various embodiments of the present invention. Referring to FIG. 3(a), the SIP module 100 includes a printed circuit board 101 with a cavity formed in a bottom surface thereof, a first device 103 mounted in the cavity 102, a circuit pattern 104 formed on a cavity undersurface 103a and electrically connected to the first device 103, second devices 111 mounted on a printed circuit board surface 103b corresponding to the cavity undersurface 103a and a resin encapsulant 112 for covering the second devices 111.

First, the printed circuit board 101 will be examined. The printed circuit board 101 is a multi-level structure with a thin substrate body made of glass-epoxy resin containing glass fiber or of BT resin and circuit patterns formed on upper and lower surfaces of the substrate body. As shown in FIG. 3(a), the printed circuit board 101 has the cavity formed therein. In FIG. 3(a), the embodiment is exemplified by only one cavity 102, but the present invention is not limited to such, and there may be a plurality of cavities formed in the printed circuit board 101. At this time, the plurality of cavities 102 can be configured to have different depths depending on the devices to be mounted therein. It is preferable that the cavity is formed in such a depth that the device is completely enclosed in the cavity.

Well-known machining techniques such as router machining can be applied to form the cavity 102 in the printed circuit board 101. Mounting the device inside the cavity 102 allows miniaturization and slimming of the SIP module.

The circuit pattern 104 is formed of conductive metal on the cavity undersurface 103a. The circuit pattern 104 is electrically connected to the device, providing a transmission path of an electric signal. The circuit pattern 104 can be plated typically with conductive material such as Au or Ni to prevent oxidation.

As shown in FIG. 3(a), the first device 103 can be a bare chip. A bare chip is cut out of a wafer and advantageous for cost reduction used as the first device 103. The bare chip is electrically connected to the circuit pattern of the printed circuit board 101 by wires. That is, a chip pad (not shown) formed on the bare chip is wire-bonded to the circuit pattern 104 formed on the cavity undersurface 103a.

FIGS. 3(b) and 3(c) are sectional views illustrating SIP modules 100′ and 100″ according to other embodiments in which at least two devices are mounted inside the cavity. Referring to FIG. 3(b), at least two first devices 113 and 114 are stacked and mounted in the cavity 102. In this case, in order to shield electromagnetic waves, an electromagnetic wave shielding layer (not shown) can be formed between the devices 113 and 114. However, it is preferable that the height of the stacked devices does not exceed the depth of the cavity.

As shown in FIG. 3(c), at least two devices 123, 124 and 125 can be mounted, in an array, on only one cavity undersurface 103a. Therefore, a plurality of devices can be mounted on one cavity undersurface in an array or in a stacked structure, thereby miniaturizing the size of the SIP module while including more functions in the SIP module.

According to the present invention, the cavity 102 is formed in the printed circuit board 101 and the first devices 103; 113 and 114; 123, 124 and 125 are mounted in the cavity 102, advantageously decreasing the height of the module. That is, as the first devices 103; 113 and 114; 123, 124 and 125 are completely enclosed in the cavity 102, the height of the entire module is decreased as much as the thickness of the first devices 103; 113 and 114; 123, 124 and 125, easily obtaining a slim and miniaturized SIP module.

In order to protect electric operation of the first devices, a resin encapsulant 106 is formed in the cavity 102 where the first devices 103; 113 and 114; 123, 124 and 125 are mounted. This resin encapsulant 106 can be formed in a space extended from the cavity undersurface 103a to the lower surface C of the printed circuit board 101, thereby covering the first device 103 and the circuit pattern 104 connected to the first device. The resin encapsulant 106 can be formed by transfer molding using Epoxy Molding Compound (EMC). In addition, the resin encapsulant 103 may also be formed by a coating method in which liquid-type resin is applied on the device and its vicinity and cured.

The module can further include at least one second device 111 mounted on a printed circuit board surface 103b corresponding to the cavity undersurface. The second devices 111 may include various types of devices such as passive and active devices. A circuit pattern 104b is formed on the printed circuit board surface 103b and electrically connected to the second devices 111, similar to the cavity undersurface 103a. In the case where the second devices are bare chips, the second devices are connected to the printed circuit of the printed circuit board 101 by the wires 105. That is, the chip pad (not shown) formed on the bare chips 111 is wire-bonded to the printed circuit 104b formed on the printed circuit board surface 103b. Therefore, the devices can be mounted on both sides of the printed circuit board 101 so as to shield the electromagnetic waves between the devices.

The second devices 111 can be encapsulated by a resin encapsulant 112. That is, the resin encapsulant 112 is formed to protect the at least one second device 111, mounted on the printed circuit board surface 103b, from the outside environment. The resin encapsulant 112 is formed to cover the printed circuit board surface 103b where the second devices 111 are mounted. The resin encapsulant 112 can be formed by transfer molding using Epoxy Molding Compound (EMC). Such molding method is suitable for mass production, improving productivity.

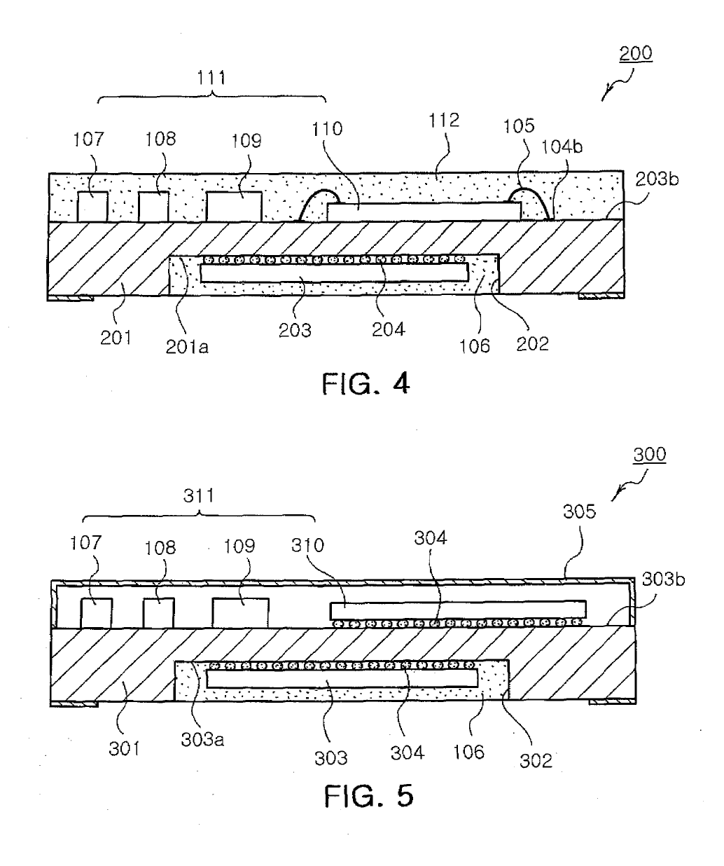

FIG. 4 is a sectional view illustrating an SIP module according to another embodiment of the present invention.

Referring to FIG. 4, the SIP module 200 is similar to the one shown in FIG. 3 in that it includes a printed circuit board 201 with a cavity 202 formed in an undersurface thereof, a first device 203 mounted inside the cavity 202, a circuit pattern 104b formed on a cavity undersurface 203a and electrically connected to the device, second devices 111 mounted on a printed circuit board surface 203b corresponding to the cavity undersurface 203b, and a resin encapsulant for covering the second devices 111. However, the difference is that the first device 203 is mounted in the cavity 202 by flip chip bonding in this embodiment. That is, the chip pad (not shown) of the first device 203 can be electrically connected to a circuit pattern (not shown) formed on the cavity undersurface 203 by an electric connection means, for example, bumps 204. The bumps 204 are formed with gold or solder on the chip pad (not shown) of the first device 203 before flip chip bonding the device 203. Flip chip bonding can be done by applying a predetermined temperature of heat and compressing while the bumps 204 are placed in contact with the circuit pattern of the cavity undersurface 203a.

In the case of flip chip bonding, the first device 203 is electrically connected to the printed circuit board 201 by use of bumps 204, and thus inductance and resistance are significantly decreased compared to the wire bonding. Also in terms of structure, power is supplied directly from the printed circuit board 201, resulting in less voltage variation compared to the former embodiment where the bare chips are connected by wires.

Although not shown in the drawings, the first device 203 may be an IC chip of a Chip Scale Package (CSP) type. The IC chip of CSP type can also be mounted on the cavity undersurface 203a without wire bonding.

FIG. 5 is a sectional view illustrating an SIP module according to further another embodiment of the present invention.

Referring to FIG. 5, the SIP module 300, which is a variation from the embodiment shown in FIG. 3, has a difference in that not only the first device 303 is mounted inside the cavity 302 by flip chip bonding but also a second device 310 is mounted on the printed circuit board surface 303b corresponding to the cavity undersurface 303a by flip chip bonding. In addition, in the embodiment shown in FIG. 3, the second devices 111 are covered by a resin encapsulant whereas in the embodiment shown in FIG. 5, a shield case 305 is used to cover the second devices 311. The shield case 305 may be made of a metal plate such as a BeCu plate, a nickel-silver plate and a tin plate. The shield case 305 has a function of shielding electromagnetic waves and protecting the second devices 311 mounted on the printed circuit board 301 from the outside environment.

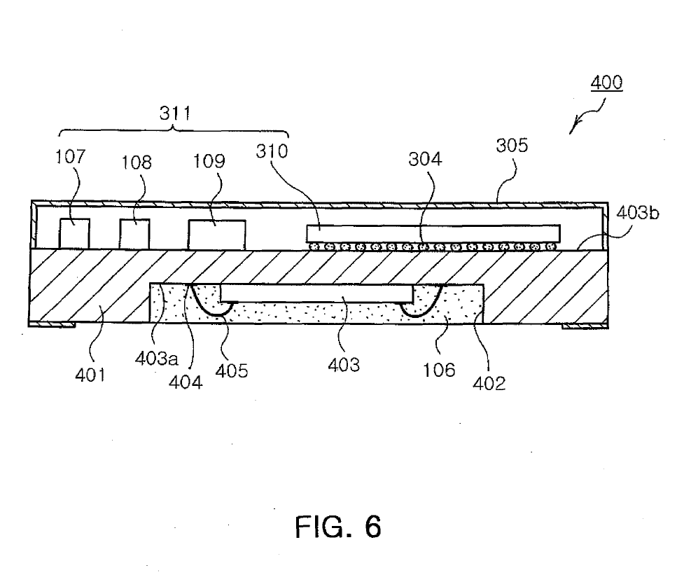

FIG. 6 is a sectional view illustrating an SIP module according to yet another embodiment of the present invention.

Referring to FIG. 6, the SIP module 400, which is a variation from the embodiment shown in FIG. 3, has a difference in that the first device 403 mounted on the cavity undersurface 403a is electrically connected to the circuit pattern 404 by wires whereas the second devices 310 are mounted to the printed circuit board surface 403b corresponding to the cavity undersurface 403b by flip chip bonding. In addition, in the embodiment shown in FIG. 3, the second devices 111 are covered by a resin encapsulant but in the embodiment shown in FIG. 5, a shield case 305 is used to cover the second devices 311.

According to the present invention set forth above, a cavity is formed in a printed circuit board to mount a device in the cavity, thereby miniaturizing and slimming a product. Further, the device is mounted also on the printed circuit board surface corresponding to the undersurface of the cavity to achieve further miniaturization and slimming while shielding electromagnetic waves.

While the present invention has been shown and described in connection with the preferred embodiments, it will be apparent to those skilled in the art that modifications and variations can be made without departing from the spirit and scope of the invention as defined by the appended claims.

What is claimed is:

1. A System-in-Package (SIP) module comprising:
a printed circuit board with at least one cavity formed therein;
at least one first device mounted in the cavity;
a circuit pattern formed on an undersurface of the cavity and electrically connected to the first device; and
at least one second device mounted to a printed circuit board surface corresponding to the undersurface of the cavity.

2. The SIP module according to claim 1, wherein a plurality of first devices are mounted in one cavity.

3. The SIP module according to claim 2, wherein the plurality of first devices are mounted on the undersurface of the cavity in a stacked structure.

4. The SIP module according to claim 1, further comprising a resin encapsulant for sealing the first device.

5. The SIP module according to claim 1, further comprising a resin encapsulant for encapsulating the second device.

6. The SIP module according to claim 1, further comprising a shield case for covering the second device.

7. The SIP module according to claim 1, wherein the first device is electrically connected to the circuit pattern by wire bonding.

8. The SIP module according to claim 1, wherein the first device is electrically connected to the circuit pattern by flip chip bonding.
